(19) United States
(12) Patent Application Publication
(10) Pub. No.: US 2006/0160348 A1
(43) Pub. Date: Jul. 20, 2006

(54) Semiconductor element with under bump metallurgy structure and fabrication method thereof

(75) Inventors: Han-Ping Pu, Taichung (TW); Chun-Chi Ke, Taichung (TW); Kuo-Jui Tai, Taichung (TW); Cheng-Hsu Hsiao, Taichung (TW)

Correspondence Address: EDWARDS & ANGELL, LLP, P.O. BOX 55874, BOSTON, MA, 02205, US

(73) Assignee: Siliconware Precision Industries Co., Ltd., Taichung Hsien (TW)

(21) Appl. No.: 11/100,140

(22) Filed: Apr. 5, 2005

(30) Foreign Application Priority Data
Jan. 18, 2005 (TW) 094101391

(51) Int. Cl. H01L 21/44

(52) U.S. Cl. 438/613

(57) ABSTRACT

A semiconductor element with under bump metallurgy (UBM) structures and a fabrication method thereof are proposed. When UBM structures are formed on signal pads and ground pads on a surface of the semiconductor element that is completely fabricated with a circuit layout, a metallic layer for defining the UBM structures is retained, wherein the UBM structures on the ground pads are electrically connected to the metallic layer, and the UBM structures on the signal pads are electrically insulated from the metallic layer. This allows the metallic layer for defining the UBM structures to directly serve as a grounding layer for the semiconductor element.

### FIELD OF THE INVENTION

The present invention relates to semiconductor elements with under bump metallurgy (UBM) structures and fabrication methods thereof, and more particularly, to a semiconductor element with UBM structures, wherein a grounding plane is integrated in the semiconductor element, and a fabrication method of the semiconductor element.

### BACKGROUND OF THE INVENTION

Flip-chip semiconductor packaging technology is an advanced packaging technique, which primarily differs from a non-flip-chip packaging technique in that a semiconductor chip incorporated in the flip-chip package is mounted on a substrate in a face-down manner and is electrically connected to the substrate by a plurality of solder bumps. Therefore, the flip-chip package does not require the use of bonding wires, which occupy relatively larger space, for establishing electrical connection between the semiconductor chip and the substrate, such that the overall flip-chip package can be made more compact in size with a reduced weight.

As shown in FIG. 1, in order to bond a solder bump 150 to a semiconductor chip 100, it is firstly necessary to form an under bump metallurgy (UBM) structure 130 on an input/output (I/O) pad 110 of the semiconductor chip 100. The UBM structure 130 comprises a metallic adhesive layer 130a such as an aluminum layer formed on the I/O pad 110; a barrier layer 130b such as a nickel/vanadium layer for preventing diffusion; and a solder wettable layer 130c such as a copper layer for bonding the solder bump 150. The UBM structure 130 can provide functions such as bump bonding, diffusion barrier, adequate adhesion and so on between the solder bump 150 and the I/O pad 110 of the semiconductor chip 100. Therefore, a solder material can be applied on the UBM structure and reflowed to form a desirable solder bump, and the UBM structure provides good bonding strength between the I/O pad and the solder bump.

A general technique for fabricating the UBM structure comprises such as sputtering, evaporation, plating and so on, as disclosed in U.S. Pat. Nos. 5,268,072, 5,503,286, 5,937,320 and 6,297,140, etc.

In accordance with operation of a high-frequency electronic product having high frequency and low voltage properties, generally a grounding layer is provided in a substrate for carrying a semiconductor chip in a semiconductor package during package fabrication processes so as to effectively improve reliability of the electronic product. Particularly, the larger and closer grounding layer to the semiconductor chip, the better electrical effects can be provided. Accordingly, there has been proposed directly mounting a grounding layer in a chip in the semiconductor industry.

FIG. 2 shows a chip structure integrated with a grounding layer as disclosed in U.S. Pat. No. 6,627,999. As shown in FIG. 2, a first dielectric layer 221, a grounding layer 222 and a second dielectric layer 223 are successively formed on a surface of a semiconductor chip 200 having at least one bond pad 210 thereon. Then, at least one first opening 231 is provided in the first dielectric layer 221 at a position corresponding to the bond pad 210, and at least one second opening 232 is provided in the second dielectric layer 223. First and second metallic interconnection structures 241, 242 are formed in the first and second openings 231, 232 respectively, so as to finally form a signal bump 251 and a ground bump 252 on the first metallic interconnection structure 241 and the second metallic interconnection structure 242 respectively. As a result, the grounding layer 222, the second metallic interconnection structure 242 and the ground bump 252 form a grounding path for the semiconductor chip 200.

However, in conventional fabrication processes for a substrate and a chip, to improve the electrical quality of a semiconductor package, the original circuit layout of the substrate or chip must be altered for either case of mounting a grounding layer in the substrate or in the chip. This not only requires additional fabrication processes and complicates the overall fabrication processes, but also increases the fabrication cost. Even in the case of forming the grounding layer on the chip surface as disclosed in U.S. Pat. No. 6,627,999, it still requires additional processes for forming the first and second dielectric layers and the grounding layer, such that the fabrication processes are still complicated and the cost cannot be effectively reduced.

### SUMMARY OF THE INVENTION

In light of the above drawbacks in the prior art, an objective of the present invention is to provide a semiconductor element with under bump metallurgy (UBM) structures and a fabrication method thereof, wherein a grounding layer is directly provided in the semiconductor element to improve electrical performances of a high frequency product.

Another objective of the present invention is to provide a semiconductor element with UBM structures and a fabrication method thereof, whereby a grounding layer can be additionally provided in the semiconductor element without having to alter circuit layouts of a substrate and a chip in a semiconductor package, so as to improve electrical quality, simplify fabrication processes and reduce fabrication costs for the semiconductor package.

In accordance with the above and other objectives, the present invention proposes a fabrication method of semiconductor element with UBM structures, comprising the steps of: preparing a semiconductor element formed with a plurality of bond pads on a surface thereof, and applying a passivation layer on the surface of the semiconductor element, wherein the passivation layer has a plurality of openings for exposing the bond pads, and the bond pads comprise signal pads and ground pads; forming a metallic layer on the semiconductor element to cover the bond pads and the passivation layer; and patterning the metallic layer to define UBM structures formed on the signals pads and ground pads, wherein the UBM structures on the signal pads are electrically insulated from the metallic layer, and the UBM structures on the ground pads are electrically connected to the metallic layer, such that the metallic layer for defining the UBM structures can serve as a grounding layer to improve electrical quality of the semiconductor element. Subsequently, solder bumps can be formed on the UBM structures on the signal pads and ground pads. Alternatively, a dielectric layer is formed on the semiconductor element to cover the metallic layer and the UBM structures, and then the dielectric layer is patterned to expose the UBM structures, such that solder bumps can be implanted on the UBM structures.

In another embodiment of the fabrication method of semiconductor element with UBM structures according to the present invention, firstly, a first UBM structure is formed on each of the signal pads and ground pads on the surface of the semiconductor element. Then, a dielectric layer is applied on the first UBM structures and is patterned to expose the first UBM structures. Subsequently, a metallic layer is formed on the dielectric layer and the first UBM structures, and is patterned to define second UBM structures corresponding to the first UBM structures on the signal pads and ground pads. The second UBM structures on the signal pads are electrically insulated from the metallic layer, and the second UBM structures on the ground pads are electrically connected to the metallic layer. Afterwards, solder bumps can be formed on the second UBM structures. Alternatively, a patterned dielectric layer is formed on the second UBM structures, and then solder bumps are implanted on the second UBM structures.

By the foregoing fabrication method, the present invention also proposes a semiconductor element with UBM structures, comprising a semiconductor element body formed with a plurality of bond pads on a surface thereof, wherein the bond pads comprise signal pads and ground pads; a passivation layer applied on the surface of the semiconductor element body, and having a plurality of openings for exposing the bond pads; a metallic layer formed on the bond pads and the passivation layer, and for defining UBM structures formed on the signal pads and ground pads, wherein the UBM structures on the signal pads are electrically insulated from the metallic layer, and the UBM structures on the ground pads are electrically connected to the metallic layer. Moreover, solder bumps are formed on the UBM structures on the signal pads and ground pads. Alternatively, a patterned dielectric layer is provided on the metallic layer and exposes the UBM structures, such that solder bumps are implanted on the UBM structures.

The semiconductor element with UBM structures according to another embodiment of the present invention comprises a semiconductor element body formed with a plurality of bond pads on a surface thereof, wherein the bond pads comprise signal pads and ground pads; a passivation layer applied on the surface of the semiconductor element body, and having a plurality of openings for exposing the bond pads; first UBM structures formed on the bond pads; a dielectric layer applied on the semiconductor element body and covering the first UBM structures, wherein the dielectric layer has a plurality of openings for exposing the first UBM structures; a metallic layer formed on the dielectric layer and the first UBM structures, and for defining second UBM structures corresponding to the first UBM structures on the signal pads and ground pads, wherein the second UBM structures on the signal pads are electrically insulated from the metallic layer, and the second UBM structures on the ground pads are electrically connected to the metallic layer. Moreover, solder bumps are formed on the second UBM structures on the signal pads and ground pads. Alternatively, a patterned dielectric layer is provided on the metallic layer and exposes the second UBM structures, such that solder bumps are implanted on the second UBM structures.

Therefore, by the semiconductor element with UBM structures and the fabrication method thereof in the present invention, when UBM structures are formed on signal pads and ground pads on a surface of a semiconductor element that is completely fabricated with an integrated circuit layout, a metallic layer for defining the UBM structures is retained, allowing the UBM structures on the ground pads to be electrically connected to the metallic layer and the UBM structures on the signal pads to be electrically insulated from the metallic layer, such that the metallic layer for defining the UBM structures directly serves as a grounding layer for the semiconductor element. This allows a grounding layer to be formed for a wafer or chip in a semiconductor package without having to alter an integrated circuitry layout of the wafer or chip and a circuit layout of a substrate for carrying the chip in the semiconductor package, such that electrical performances of a high frequency electronic product can be improved without increasing fabrication processes and costs thereof.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a cross-sectional view of a conventional under bump metallurgy (UBM) structure;

FIG. 2 (PRIOR ART) is a cross-sectional view of a conventional chip integrated with a grounding layer as disclosed in U.S. Pat. No. 6,627,999;

FIGS. 3A to 3D are cross-sectional schematic diagrams showing steps of a fabrication method of semiconductor element with UBM structures according to a first preferred embodiment of the present invention;

FIG. 4 is a top view of a semiconductor element with UBM structures according to the first preferred embodiment of the present invention;

FIG. 5 is a cross-sectional view of the semiconductor element with UBM structures according to a second preferred embodiment of the present invention;

FIGS. 6A to 6F are cross-sectional schematic diagrams showing steps of the fabrication method of semiconductor element with UBM structures according to a third preferred embodiment of the present invention; and

FIG. 7 is a cross-sectional view of the semiconductor element with UBM structures according to a fourth preferred embodiment of the present invention.

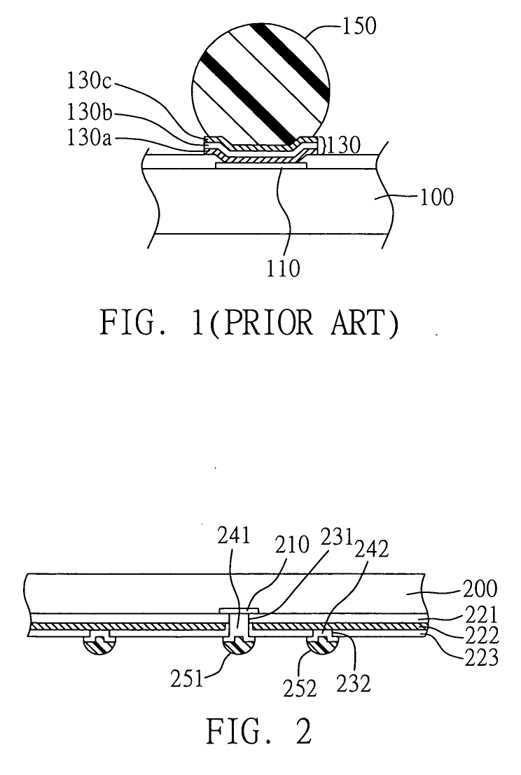

### DETAILED DESCRIPTION OF THE PREFERRED EMBODIMENTS

### First Preferred Embodiment

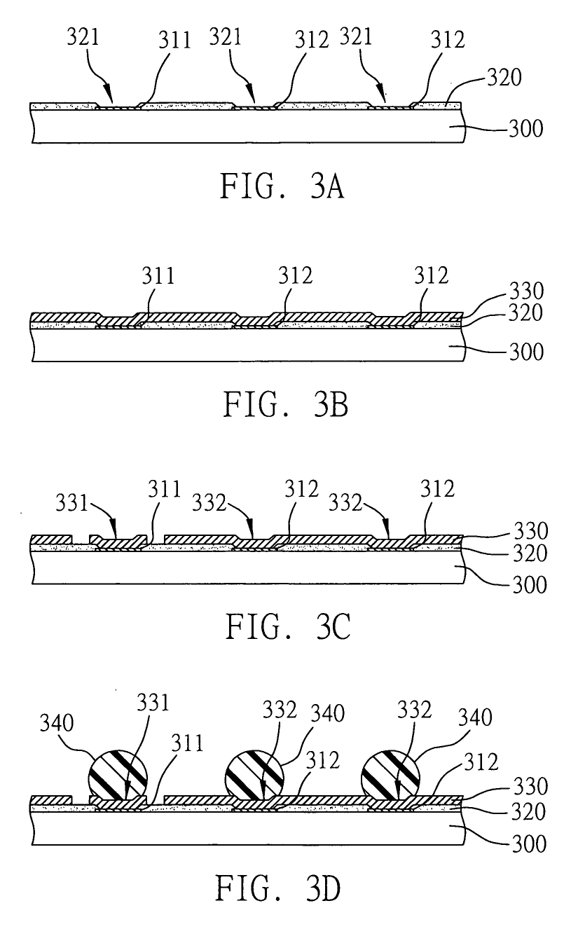

FIGS. 3A to 3D are cross-sectional schematic diagrams showing steps of a fabrication method of semiconductor element with under bump metallurgy (UBM) structures according to a first preferred embodiment of the present invention.

Referring to FIG. 3A, firstly, a semiconductor element 300 is provided, wherein a plurality of bond pads 311, 312 are formed on a surface of the semiconductor element 300. A passivation layer 320 is provided on the surface of the semiconductor element 300, and is formed with a plurality of openings 321 for exposing the bond pads 311, 312. The bond pads 311, 312 comprise signal pads 311 and ground pads 312 according to functional properties thereof. The semiconductor element 300 is suitable for a semiconductor package substrate structure, or can be applied to a general printed circuit board for assembly of electronic elements at a second stage, but preferably the semiconductor element 300 is applied to a flip-chip type of semiconductor chip or wafer. The bond pads 311, 312 serve as input/output (I/O) connections for internal circuits of the semiconductor element 300. The passivation layer 320 is a dielectric layer such as a polyimide layer, a silicon dioxide layer, a silicon nitride layer and so on employed in general fabrication processes. The passivation layer 320 is used to cover the surface of the semiconductor element 300 and protect it against contamination and damage from an external environment.

Referring to FIG. 3B, a metallic layer 330 is applied on the semiconductor element 300 by a physical or chemical deposition technique such as sputtering, evaporation, electroplating and so on to cover the passivation layer 320 and the bond pads 311, 312. The metallic layer 330 is not limited to one layer but can be adjusted in its number of layers and types according to practical fabrication requirements, so as to allow subsequent solder bumps to be effectively bonded thereto, for example, the metallic layer may comprise a metallic adhesive layer (such as an aluminum metal layer), a barrier layer (such as a nickel-vanadium alloy layer) and a solder wettable layer (such as a copper metal layer).

Referring to FIG. 3C, the metallic layer 330 is patterned to define UBM structures 331, 332 formed on the signal pads 311 and ground pads 312 respectively. The UBM structures 331 on the signal pads 311 are electrically insulated from the metallic layer 330, and the UBM structures 332 on the ground pads 312 are electrically connected to the metallic layer 330. This allows the metallic layer 330 for defining the UBM structures 331, 332 to serve as a grounding layer for improving electrical quality of the semiconductor element 300.

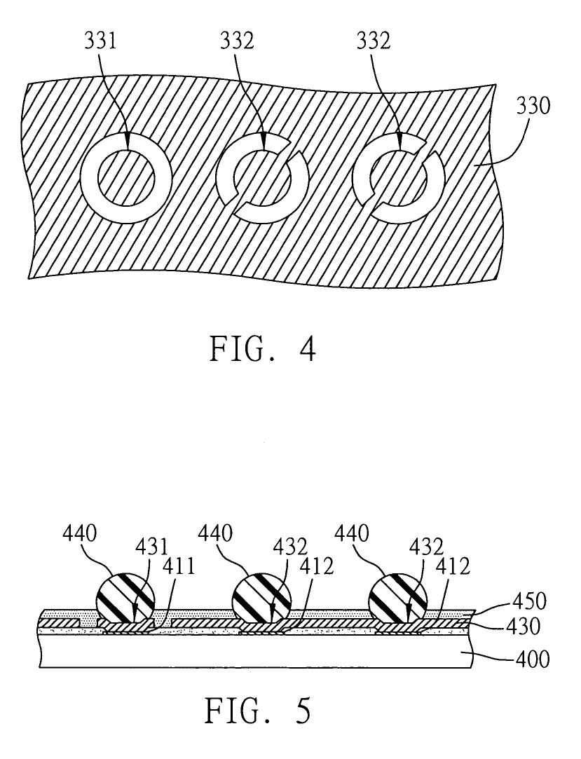

The patterning process for the metallic layer 330 is performed by firstly applying a resist layer such as a photoresist layer (not shown) on the metallic layer 330, then forming a plurality of openings in the resist layer via exposing and developing techniques, etc. to expose the metallic layer, and subsequently patterning the metallic layer at positions corresponding to the signal pads and ground pads via an etching process, such that the UBM structures 331, 332 respectively electrically insulated from and electrically connected to the metallic layer 330 can be defined on the signal pads 311 and ground pads 312. As shown in FIG. 4 of a top view of the semiconductor element, the UBM structures 331 on the signal pads 311 are electrically insulated from the metallic layer 330, and the UBM structures 332 on the ground pads 312 are electrically connected to the metallic layer 330, such that the metallic layer 330 for defining the UBM structures 331, 332 can serve as a grounding layer to improve electrical quality of the semiconductor element 300. This allows the metallic layer 330 for making the UBM structures 331, 332 to be directly used as the grounding layer without altering a circuit layout of the semiconductor element, thereby effectively reducing fabrication costs and simplifying fabrication processes.

Referring to FIG. 3D, then solder bumps 340 can be formed on the UBM structures 331, 332 on the signal pads 311 and ground pads 312 respectively.

Therefore, by the foregoing fabrication method, the present invention discloses a semiconductor element with UBM structures, comprising a body of semiconductor element 300 formed with a plurality of bond pads 311, 312 on a surface thereof, wherein the bond pads 311, 312 comprise signal pads 311 and ground pads 312; a passivation layer 320 applied on the body of semiconductor element 300 and having a plurality of openings for exposing the bond pads 311, 312; a metallic layer 330 formed on the bond pads 311, 312 and the passivation layer 320, and for defining UBM structures 331, 332 formed on the signal pads 311 and ground pads 312 respectively, wherein the UBM structures 331 on the signal pads 311 are electrically insulated from the metallic layer 330, and the UBM structures 332 on the ground pads 312 are electrically connected to the metallic layer 330. Moreover, solder bumps 340 can be formed on the UBM structures 331, 332.

### Second Preferred Embodiment

As shown in FIG. 5, which is a cross-sectional view of the semiconductor element with UBM structures according to a second preferred embodiment of the present invention, the fabrication method and structure of the second embodiment are substantially the same as those of the first embodiment, with a primary difference in that in the second embodiment, after a patterned metallic layer 430 defines UBM structures 431, 432 on signal pads 411 and ground pads 412 respectively, a dielectric layer 450 is applied on the metallic layer 430 and the UBM structures 431, 432 and is patterned to expose the UBM structures 431, 432. Then, solder bumps 440 are formed on the UBM structures 431, 432.

### Third Preferred Embodiment

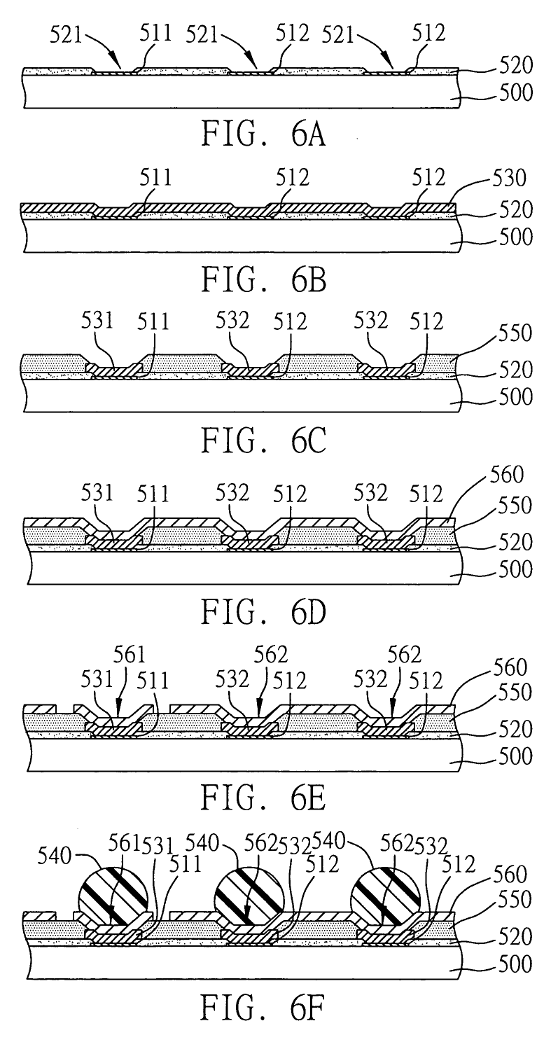

As shown in FIGS. 6A to 6F, which are cross-sectional schematic diagrams of the semiconductor element with UBM structures according to a third preferred embodiment of the present invention, the fabrication method and structure of the third embodiment are substantially the same as those of the first embodiment, with a primary difference in that in the third embodiment, after first UBM structures are formed on the bond pads of the semiconductor element, a dielectric layer and a metallic layer that is for defining second UBM structures are successively formed and serve as a grounding layer for the semiconductor element.

Referring to FIG. 6A, a semiconductor element 500 formed with a plurality of bond pads 511, 512 on a surface thereof is provided. A passivation layer 520 is applied on the semiconductor element 500 and has a plurality of openings 521 for exposing the bond pads 511, 512. The bond pads 511, 512 comprise signal pads 511 and ground pads 512.

Referring to FIG. 6B, a metallic layer 530 is formed on the semiconductor element 500 to cover the bond pads 511, 512 and the passivation layer 520. The number of layers and types of the metallic layer 530 can be adjusted according to practical fabrication requirements; for example, the metallic layer may comprise a metallic adhesive layer (such as an aluminum metal layer), a barrier layer (such as a nickel-vanadium alloy layer) and a solder wettable layer (such as a copper metal layer).

Referring to FIG. 6C, the metallic layer 530 is patterned to define first UBM structures 531, 532 on the signal pads 511 and ground pads 512 respectively. Then, a dielectric layer 550 is formed on the semiconductor element 500 and covers the first UBM structures 531, 532. The dielectric layer 550 is patterned to expose the first UBM structures 531, 532.

Referring to FIG. 6D, another metallic layer 560 is formed on the dielectric layer 550 and the first UBM structures 531, 532. The metallic layer 560 can be made of a same or different material as or from the foregoing metallic layer 530, and can be adjusted in its number of layers and types according to practical fabrication requirements to allow subsequent solder bumps to be effectively bonded thereto.

Referring to FIG. 6E, the metallic layer 560 is patterned to define second UBM structures 561, 562 corresponding to the first UBM structures 531, 532 on the signal pads 511 and ground pads 512 respectively. The second UBM structures 561 on the signal pads 511 are electrically insulated from the metallic layer 560, and the second UBM structures 562 on the ground pads 512 are electrically connected to the metallic layer 560, such that the metallic layer 560 for defining the second UBM structures 561, 562 can serve as a grounding layer to improve electrical quality of the semiconductor element 500.

Referring to FIG. 6F, solder bumps 540 can be formed on the second UBM structures 561, 562.

### Fourth Preferred Embodiment

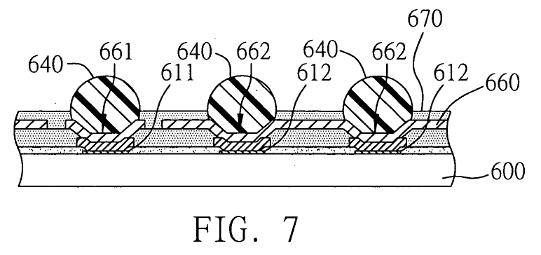

As shown in FIG. 7, which is a cross-sectional schematic diagram of the semiconductor element with UBM structures according to a fourth preferred embodiment of the present invention, the fabrication method and structure of the fourth embodiment are substantially the same as those of the third embodiment, with a primary difference in the location of signal pads 611 and ground pads 612 of the semiconductor element 600. In the fourth embodiment, after patterning a metallic layer 660 to form second UBM structures 661, 662, firstly a dielectric layer 670 is formed on the semiconductor element 600 to cover the metallic layer 660 and the second UBM structures 661, 662, and is patterned to expose the second UBM structures 661, 662. Then, solder bumps 640 are formed on the second UBM structures 661, 662.

Therefore, by the semiconductor element with UBM structures and the fabrication method thereof in the present invention, when UBM structures are formed on signal pads and ground pads on a surface of a semiconductor element that is completely fabricated with an integrated circuit layout, a metallic layer for defining the UBM structures is retained, allowing the UBM structures on the ground pads to be electrically connected to the metallic layer and the UBM structures on the signal pads to be electrically insulated from the metallic layer, such that the metallic layer for defining the UBM structures directly serves as a grounding layer for the semiconductor element. This allows a grounding layer to be formed for a wafer or chip in a semiconductor package without having to alter an integrated circuitry layout of the wafer or chip and a circuit layout of a substrate for carrying the chip in the semiconductor package, such that electrical performances of a high frequency electronic product can be improved without increasing fabrication processes and costs thereof.

The present invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A fabrication method of semiconductor element with under bump metallurgy (UBM) structures, comprising the steps of:
providing a semiconductor element formed with a plurality of bond pads on a surface thereof, and applying a passivation layer on the surface of the semiconductor element, the passivation layer having a plurality of openings for exposing the bond pads, wherein the bond pads comprise signal pads and ground pads;
forming a metallic layer on the semiconductor element to cover the bond pads and the passivation layer; and
patterning the metallic layer to define UBM structures formed on the signal pads and ground pads, wherein the UBM structures on the signal pads are electrically insulated from the metallic layer, and the UBM structures on the ground pads are electrically connected to the metallic layer.

2. The fabrication method of claim 1, wherein the metallic layer for defining the UBM structures serves as a grounding layer to improve electrical quality of the semiconductor element.

3. The fabrication method of claim 1, further comprising a step of forming solder bumps on the UBM structures on the signal pads and ground pads.

4. The fabrication method of claim 1, further comprising the steps of:
forming a dielectric layer on the semiconductor element to cover the metallic layer and the UBM structures;
patterning the dielectric layer to expose the UBM structures; and
forming solder bumps on the UBM structures.

5. The fabrication method of claim 1, wherein the semiconductor element is one selected from the group consisting of a semiconductor chip, wafer, semiconductor package substrate and circuit board.

6. A fabrication method of semiconductor element with UBM structures, comprising the steps of:
providing a semiconductor element formed with a plurality of bond pads on a surface thereof, and applying a passivation layer on the surface of the semiconductor element, the passivation layer having a plurality of openings for exposing the bond pads, wherein the bond pads comprise signal pads and ground pads;
forming a first metallic layer on the semiconductor element to cover the bond pads and the passivation layer;
patterning the first metallic layer to define first UBM structures formed on the signal pads and ground pads;
forming a first dielectric layer on the semiconductor element, and patterning the first dielectric layer to expose the first UBM structures;
forming a second metallic layer on the first dielectric layer and the first UBM structures; and
patterning the second metallic layer to define second UBM structures corresponding to the first UBM structures on the signal pads and ground pads, wherein the second UBM structures on the signal pads are electrically insulated from the second metallic layer, and the second UBM structures on the ground pads are electrically connected to the second metallic layer.

7. The fabrication method of claim 6, wherein the second metallic layer for defining the second UBM structures serves as a grounding layer to improve electrical quality of the semiconductor element.

8. The fabrication method of claim 6, further comprising a step of forming solder bumps on the second UBM structures on the signal pads and ground pads.

9. The fabrication method of claim 6, further comprising the steps of:
forming a second dielectric layer on the semiconductor element to cover the second metallic layer and the second UBM structures;
patterning the second dielectric layer to expose the second UBM structures; and
forming solder bumps on the second UBM structures.

10. The fabrication method of claim 6, wherein the semiconductor element is one selected from the group consisting of a semiconductor chip, wafer, semiconductor package substrate and circuit board.

11. A semiconductor element with UBM structures, comprising:
a semiconductor element body formed with a plurality of bond pads on a surface thereof, wherein the bond pads comprise signal pads and ground pads;
a passivation layer applied on the surface of the semiconductor element body, and having a plurality of openings for exposing the bond pads; and
a metallic layer formed on the bond pads and the passivation layer, and for defining UBM structures formed on the signal pads and ground pads, wherein the UBM structures on the signal pads are electrically insulated from the metallic layer, and the UBM structures on the ground pads are electrically connected to the metallic layer.

12. The semiconductor element of claim 11, wherein the metallic layer for defining the UBM structures serves as a grounding layer to improve electrical quality of the semiconductor element.

13. The semiconductor element of claim 11, further comprising solder bumps formed on the UBM structures on the signal pads and ground pads.

14. The semiconductor element of claim 11, further comprising:
a dielectric layer formed on the semiconductor element body to cover the metallic layer and the UBM structures, the dielectric layer having openings for exposing the UBM structures; and
solder bumps formed on the UBM structures exposed via the openings of the dielectric layer.

15. The semiconductor element of claim 11, wherein the semiconductor element body is one selected from the group consisting of a semiconductor chip, wafer, semiconductor package substrate and circuit board.

16. A semiconductor element with UBM structures, comprising:
a semiconductor element body formed with a plurality of bond pads on a surface thereof, wherein the bond pads comprise signal pads and ground pads;
a passivation layer applied on the surface of the semiconductor element, and having a plurality of openings for exposing the bond pads;
first UBM structures formed on the bond pads;
a first dielectric layer formed on the semiconductor element body to cover the first UBM structures, the first dielectric layer having a plurality of openings for exposing the first UBM structures; and
a metallic layer formed on the first dielectric layer and the first UBM structures, and for defining second UBM structures corresponding to the first UBM structures on the signal pads and ground pads, wherein the second UBM structures on the signal pads are electrically insulated from the metallic layer, and the second UBM structures on the ground pads are electrically connected to the metallic layer.

17. The semiconductor element of claim 16, wherein the metallic layer for defining the second UBM structures serves as a grounding layer to improve electrical quality of the semiconductor element.

18. The semiconductor element of claim 16, further comprising solder bumps formed on the second UBM structures on the signal pads and ground pads.

19. The semiconductor element of claim 16, further comprising:
a second dielectric layer formed on the semiconductor element body to cover the metallic layer and the second UBM structures, the second dielectric layer having openings for exposing the second UBM structures; and
solder bumps formed on the second UBM structures exposed via the openings of the second dielectric layer.

20. The semiconductor element of claim 16, wherein the semiconductor element body is one selected from the group consisting of a semiconductor chip, wafer, semiconductor package substrate and circuit board.
